(19) United States
(12) Patent Application Publication
(10) Pub. No.: US 2004/0032021 A1
(43) Pub. Date: Feb. 19, 2004

(54) Structure of a heat dissipation fin

(76) Inventors: Wen-Lo Shieh, Taipei (TW); Hung Hjing, Taipei (TW)

Correspondence Address: Wen-Lo SHIEH, PO Box 82-144, Taipei, TW

(21) Appl. No.: 10/436,993

(22) Filed: May 14, 2003

(30) Foreign Application Priority Data
Aug. 16, 2002 (TW) 091212981

(51) Int. Cl. H01L 23/12; H01L 23/10; H01L 23/34; H01L 23/48; H01L 23/52; H01L 29/40

(52) U.S. Cl. 257/704; 257/710; 257/712; 257/738

(57) ABSTRACT

An improved structure of heat dissipation fin for prevention of glue-overflowing in semiconductor packaging includes a substrate and a chip bonding module, wherein the heat dissipation fin is a thin housing structure having a bottom flat section and the center position is provided with a protruded section, forming into a covering body to cover the chip and the bonding body, the top section of the protruded section is provided with a first stepped platform and the inner edge of the platform is further formed into bottom recess structure and the wall thereof is then formed vertically into a raised second stepped protruded ring, and the center at the inner edge of the second stepped protruded ring is formed into a top recessed face, thereby the first stepped ring platform and the second stepped ring platform urge the top face of the top edge of the mold to form into a structure to block the packaging adhesive such that the adhesive will not overflow into the center position of the heat dissipation fin.

### BACKGROUND OF THE INVENTION

(a) Technical Field of the Invention

The present invention relates to heat dissipation fin, and in particular, to heat dissipation fin which is used to prevent glue-overflowing in semiconductor package.

(b) Description of the Prior Art

Referring to FIGS. 1 and 1A, there is shown a conventional structure used in semiconductor packaging to prevent glue-overflow. A chip 2′ is bonded to a substrate 3′ and the external surrounding of the bonding region of the chip 2′ and the substrate 3′ a heat dissipation fin 1′ made of excellent heat dissipation material is used to cover the chip 2′ and the bonding region and is secured onto the substrate 3′. After that the chip 2′ is placed into the cavity 41′ of the mold 4′, and a packaging glue 3′ is poured into the cavity 41′ via a channel 42′, enclosing the heat dissipation fin 1′. Due to the entire flat surface of the protruded section 11′ at the top face 111′ of the heat dissipation fin 1′ urges the top face 43′ of the cavity 41′, during the pouring of glue, the packaging glue 5′ may not enter easily therein to facilitate heat transfer from the interior of the heat dissipation fin 1′ when the top face 111′ of the heat dissipation fin 1′ maintains to expose externally. As a result of the top face 111′ of the protruded section 11′ is a flat surface, after the it contacts with the top face 43′ of the cavity 41′, the contact area is large. Unless the flatness is precise, tight sealing is difficult to obtain and the packaging glue 5′ entering the top face 111′ of the protruded section 11′ will be occurred and such overflow of glue will affect the heat dissipation efficiency.

In view of the above, it is an object of the present invention to provide an improved structure of heat dissipation fin, which can solve the above-mentioned drawback.

### SUMMARY OF THE INVENTION

Accordingly, it is an object of the present invention to provide an improved structure of heat dissipation fin for prevention of glue-overflowing in semiconductor packaging having a substrate and a chip bonding module, characterized in that a heat dissipation fin structure having an adhesive blocking groove and a protruded ring is covered thereto so as to prevent the adhesive for packaging employing a mold from entering the top recess of the heat dissipation fin, wherein the heat dissipation fin is a thin housing structure having a bottom flat section and the center position is provided with a protruded section, forming into a covering body to cover the chip and the bonding body, the top section of the protruded section is provided with a first stepped platform and the inner edge of the platform is further formed into bottom recess structure and the wall thereof is then formed vertically into a raised second stepped protruded ring, and the center at the inner edge of the second stepped protruded ring is formed into a top recessed face, thereby the first stepped ring platform and the second stepped ring platform urge the top face of the top edge of the mold to form into a structure to block the packaging adhesive such that the adhesive will not overflow into the center position of the heat dissipation fin.

An aspect of the present invention to provide an improved structure of heat dissipation fin for prevention of glue-overflowing in semiconductor packaging wherein the lower section of the bottom flat surface of the heat dissipation fin is provided with a support pad.

Yet another object of the present invention is to provide an improved structure of heat dissipation fin for prevention of glue-overflowing in semiconductor packaging wherein the vertical height from the bottom section of the support pad to the top face of the second stepped protruded ring is higher than that of the mold cavity.

A further object of the present invention is to provide an improved structure of heat dissipation fin for prevention of glue-overflowing in semiconductor packaging, wherein the method of bonding between the substrate and the chip bonding mold module is by way of wire-bonding method or flip chip bonding.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic sectional view of an adhesive-overflow structure of a heat dissipation fin of a conventional semiconductor package.

FIG. 1A is an enlarged view of a portion of FIG. 1.

FIG. 2 is a top view of a heat dissipation structure in accordance with the present invention.

FIG. 3 is a sectional view along line A-A of FIG. 1 in accordance with the present invention.

FIG. 4 is a perspective and partial sectional view of the present invention.

FIG. 5 is a plastic mold of a preferred embodiment in accordance with the present invention.

FIG. 6 is a schematic view showing the packaging element in accordance with the present invention.

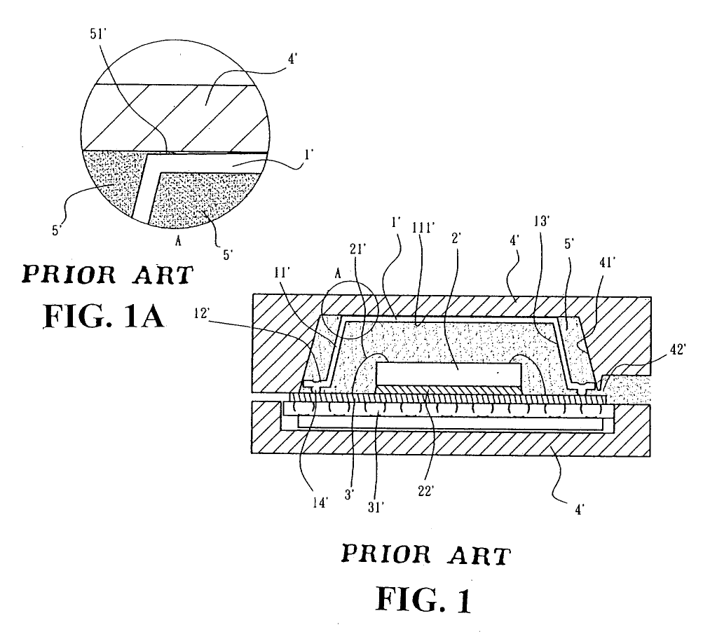

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

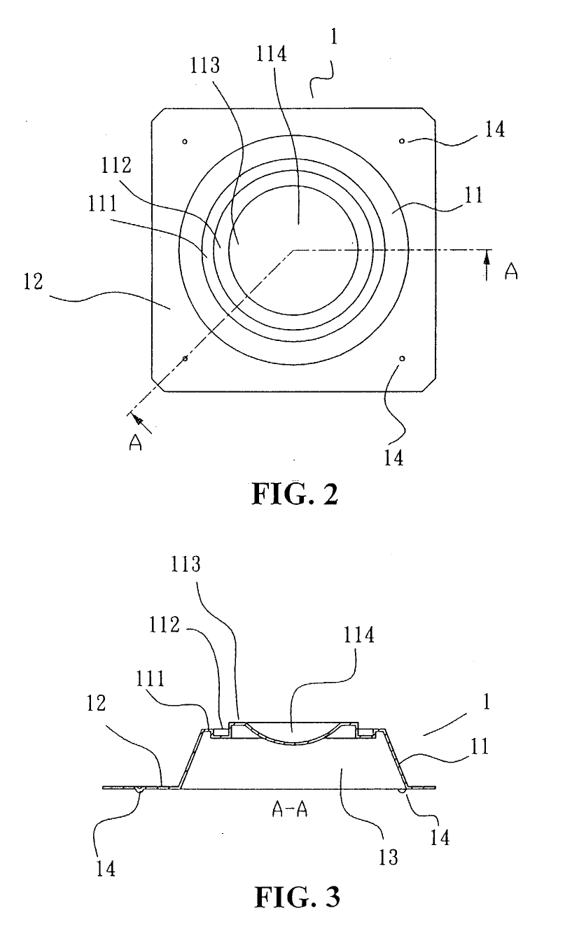

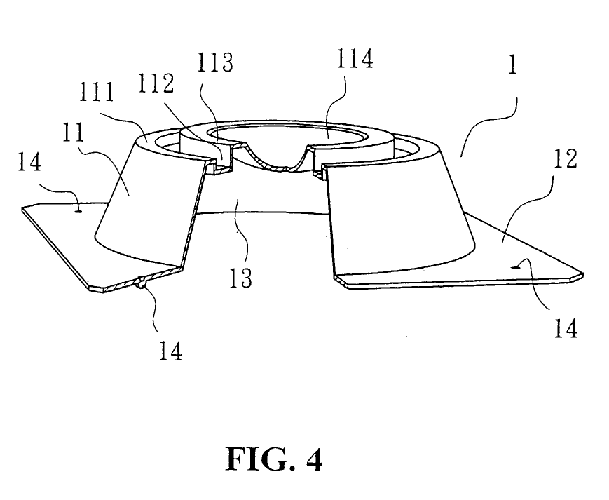

In accordance with the present invention, there is shown an improved structure of heat dissipation fin. Referring to FIGS. 2, 3 and 4, the improved structure of heat dissipation fin 1 for prevention of glue-overflowing in semiconductor packaging having a substrate 3 and a chip 2 bonding module, characterized in that the heat dissipation fin 1 is a thin housing structure having a bottom flat surface 12 and the center position is provided with a protruded section 11, forming into a covering body to cover the chip 2 and as a bonding body. The top section of the protruded section 11 is provided with a first stepped platform 111 and the inner edge of the platform 111 is further formed into bottom recess structure 112 and the wall thereof is then formed vertically into a raised second stepped protruded ring 113, and the center at the inner edge of the second stepped protruded ring 113 is formed into a top recessed face 114, thereby the first stepped ring platform 111 and the second stepped ring platform 113 urge the top face of the top edge of the mold to form into a structure to block the packaging glue such that the glue will not overflow into the center position of the heat dissipation fin 1.

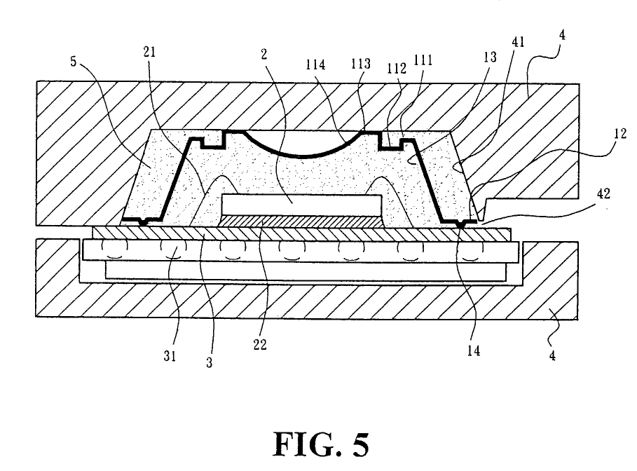

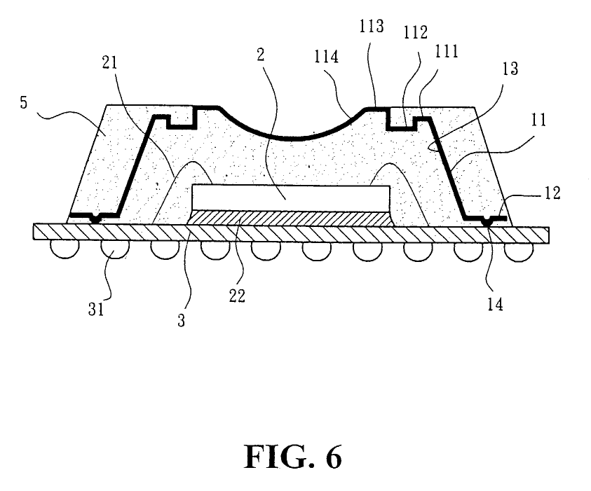

Referring to FIGS. 5 and 6, the heat dissipation fin 1 structure employs a substrate 3 and chip 2 which are bonded by way of wire-bonding method of electrically bonding. The heat dissipation fin 1 covers the chip 2 and the bonded mold module, and the protruded section 11 is used to be secured onto the substrate 3. The chip 2 is then moved to the cavity 41 of the mold 4 and the end face of the second stepped protruded ring 113 urges the top face 43 of the cavity 41 and the packaging glue 5 enters via the channel 42 so as to filled up the space of the substrate 3. Due to the face that the space between the first stepped ring plat form 111 and the bottom recessed slot 112 is close to the top face of the cavity 41, a very narrow gap is formed so as to reduce the flowing of the packaging glue 5. The end face of the second stepped protruded ring 113 is a protruded section, the area of contact is small when the top face 43 of the cavity 41 is urged and therefore the contact pressure becomes large that the overflow of glue 5 is prevented.

The top recessed face 114 of the heat dissipation fin 1 is a recessed structure the top section of the heat dissipation fin 1 becomes closer to the heat source of the chip 2 and therefore the heat transfer is rapid. That is the discharge of heat source is rapid and is concentrated onto the top face of the heat dissipation fin, and the heat transfer efficiency is excellent.

The bonding of the chip 2 onto the substrate 3, in accordance with the present invention, may employ the method of flip chip bonding. At this instance the contact surface of the heat dissipation fin 1 can be reduced.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. An improved structure of heat dissipation fin for prevention of glue-overflowing in semiconductor packaging having a substrate and a chip bonding module, characterized in that a heat dissipation fin structure having an adhesive blocking groove and a protruded ring is covered thereto so as to prevent the adhesive for packaging employing a mold from entering the top recess of the heat dissipation fin, wherein the heat dissipation fin is a thin housing structure having a bottom flat section and the center position is provided with a protruded section, forming into a covering body to cover the chip and the bonding body, the top section of the protruded section is provided with a first stepped platform and the inner edge of the platform is further formed into bottom recess structure and the wall thereof is then formed vertically into a raised second stepped protruded ring, and the center at the inner edge of the second stepped protruded ring is formed into a top recessed face, thereby the first stepped ring platform and the second stepped ring platform urge the top face of the top edge of the mold to form into a structure to block the packaging adhesive such that the adhesive will not overflow into the center position of the heat dissipation fin.

2. The improved structure of heat dissipation fin of claim 1, wherein the lower section of the bottom flat surface of the heat dissipation fin is provided with a support pad.

3. The improved structure of heat dissipation fin of claim 1, wherein the vertical height from the bottom section of the support pad to the top face of the second stepped protruded ring is higher than that of the mold cavity.

4. The improved structure of heat dissipation fin of claim 3, wherein the method of bonding between the substrate and the chip bonding mold module is by way of wire-bonding method.

5. The improved structure of heat dissipation fin of claim 3, wherein the method of bonding between the substrate and the chip bonding mold module is by way of flip-chip bonding method.
